(19) United States
(12) Patent Application Publication
(10) Pub. No.: US 2008/0277285 A1
(43) Pub. Date: Nov. 13, 2008

(54) BIPOLAR ELECTROLESS PROCESSING METHODS

(75) Inventor: Philippe M. Vereecken, Liege (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum vzw (IMEC), Leuven (BE)

(21) Appl. No.: 12/116,045

(22) Filed: May 6, 2008

Related U.S. Application Data
(60) Provisional application No. 60/916,771, filed on May 8, 2007.

(30) Foreign Application Priority Data
Oct. 31, 2007 (EP) 07119756.0

(51) Int. Cl. H01L 21/288

(52) U.S. Cl. 205/123

(57) ABSTRACT

A bipolar photo-electrochemical process is disclosed for electroless deposition (referred to as photo Bi-OCD) of a metallic compound onto the top surface of a semiconducting substrate whereby differential illumination of the front side of the substrate versus the back side of the substrate provides a driving force to separate the cathodic and anodic partial reactions leading to high yield deposition of the metallic compound. A selective photo Bi-OCD process is further disclosed whereby the top surface of the substrate is at least partly covered with an insulating pattern such that the deposition of the metallic compound takes place selectively into the openings of the pattern.

### CROSS-REFERENCE TO RELATED APPLICATIONS

This application claims the benefit under 35 U.S.C. § 119(e) of U.S. provisional application Ser. No. 60/916,771 filed on May 8, 2007, and claims the benefit under 35 U.S.C. § 119(a)-(d) of European application No. 07119756.0 filed on Oct. 31, 2007, the disclosures of which are hereby expressly incorporated by reference in their entirety and are hereby expressly made a portion of this application.

### FIELD OF THE INVENTION

The present disclosure is related to the field of bipolar electrochemical processing (Bi-ECP), more specifically to bipolar electroless processing. A method for selective electrochemical deposition of metallic particles onto a substrate is provided. Furthermore preferred embodiments are related to specific uses of a method for selective deposition of metallic nanoparticles.

### BACKGROUND OF THE INVENTION

Electrochemical deposition (or plating) methods are widely used to deposit metallic compounds onto a surface of a substrate. Both electroplating and electroless plating processes are attractive methods to deposit pure metals or alloys from metal ions in solution. Besides (metal) deposition, also electrochemical metal-removal processes are widely used and applied for electro polishing, chemical etching and electro etching.

As such, in prior art, electrochemical metal deposition is explored as one of the methods for “selective” particles placement. The placement of metal nanoparticles on e.g. silicon (Si) substrates can be done by conventional electrochemical deposition (i.e. using an external power supply) directly on the substrate.

In conventional electrochemical processing (such as electrodeposition or electro etching) an external voltage and current is applied between at least two electrodes in an electrolyte bath. One half reaction (e.g. metal deposition through metal ion reduction) proceeds at the substrate or first electrode (work piece), and a second half reaction or counter reaction proceeds at a second electrode (current collector).

The control of the half reactions is a difficulty while working with conventional electrochemical processes using external voltage and current.

Furthermore, for the direct placement of metal nanoparticles on the substrate done by conventional electrochemical deposition, a contact needs to be made to the back side of the substrate (wafer). This can be done for example by pressing the back side of the substrate to a metal plate to obtain intimate contact and thus keep the contact resistance at a minimum. Also preferentially the back side of the substrate should be highly doped (e.g. by implantation) and additionally a suitable metal (that forms an ohmic contact with the Si substrate), metal silicide or metal germanide is coated on the substrate back side to minimize the contact resistance. However, in semiconductor processing, contamination of the substrate back side is a possible issue.

Electroless deposition can avoid the use of such a contact to the substrate. However, in conventional “chemical” electroless deposition, where the metal ion solution or electrolyte further contains a reducing agent, the surface needs to be first activated with a catalyst cluster such as Pd catalyst cluster particles for the out-plating of the metal on the catalyst. Obviously this method is not suitable for the deposition of nanoparticles which need to be as small or even smaller in size as the catalyst cluster particles themselves.

Further on, in electroless deposition by galvanic displacement the surface does not need to be activated first, but plays the role of reducing species instead. Electroless deposition by galvanic displacement is characterized by a process with two half reactions: a cathodic half reaction or reduction of metal ions to form the metal clusters on the substrate surface (e.g. Si) and the anodic half reaction or the oxidation of the substrate (e.g. Si). The partial currents of both half reactions have to be equal so that no effective external current flows, i.e. the reaction occurs electroless.

The total reaction for electroless deposition by galvanic displacement is spontaneous (free enthalpy ΔG<0), which means that the substrate has to be less noble than the metal which is deposited (also metal ion concentration and complexation determine ΔG).

In the case of semiconductor substrates, there is the additional requirement that the empty electron levels (LUMO) of the metal ions overlap with the valence band of the semiconductor (for deposition in the dark).

Electroless deposition by galvanic displacement means that both reduction (e.g. deposition) and oxidation occur at the same surface. This has many implications for the quality of the deposited metal and metal substrate interface. For example when metal particles or films are deposited on a blanket Si surface, the silicon surface itself will be oxidized (i.e. forming insulating SiO₂) unless HF is added to remove the oxide which is, however, not always practically possible.

A potential drawback (or advantage, depending on the application), of electroless deposition by galvanic displacement (on the same surface) is that the deposition can be self-limiting when one of the half reactions is shutdown. Self-limitation happens when the substrate surface is completely covered and thus the underlying substrate (which is also the reducing species) is not longer available to sustain the reaction. This typically happens when either an insoluble surface oxide is formed (e.g. SiO₂ on Si substrate) during the oxidation reaction or when the surface becomes fully covered by a dense metal layer as a result of the reduction (deposition) reaction. Hence, the self-limitation can be beneficial when only small particles or dense thin films are desired, but are a drawback when oxide-free surfaces and thick (dense) films are required.

Galvanic displacement reactions are used for thick metal deposits (e.g. Ni on Si as described by Niwa et al. Electrochimica Acta 48 (2003)1295-1300), but these films are porous so that contact between substrate and solution is maintained.

Electroless deposition by galvanic displacement can also be used for selective deposition in patterns. However, here the issue is that the anodic and cathodic half reactions may randomly occur separately into different pattern features, such as holes: deposition may occur in one series of holes whereas the anodic counter reaction occurs in another set of holes. In this case, a galvanic cell is created where the half reactions are uncontrollably separated (in analogy with galvanic corrosion). This affects the yield of deposition and limits the use of electroless deposition for electrodeposition on patterned substrates.

In electroless processing, both half reactions (reduction and oxidation) occur simultaneous at one and the same substrate and no external voltage or current flow is necessary.

In bipolar electrochemistry, both half reactions also (as for electroless deposition) occur at one and the same substrate but the cathodic and anodic reactions are space separated by placing the substrate in an electric field applied between two feed electrodes. In this case no physical connection is made between the substrate and the power source. However, to drive the electrochemical reactions an external voltage and current need to be applied.

Bipolar electrochemistry, like conventional electrochemistry, requires a solution that can support the separate oxidation and reduction reactions i.e. an electrolyte. The electrolyte composition affects the electrolyte's conductivity and the electrochemistry on the isolated substrate.

Bipolar electrochemistry can be categorized into one of two arbitrary designations. First there is “open” bipolar electrochemistry and second there is “closed” bipolar electrochemistry.

Open bipolar electrochemistry occurs on an electrically and physically isolated substrate that is completely immersed in one suitable electrolyte.

In closed bipolar electrochemistry the substrate forms a barrier between the electrodes and separates the electrolyte into separate areas. The end result is that the electrolyte acts as an electrolytic wire between the feeder electrodes and the substrate.

A well-known example of closed bipolar electrochemistry can be found in fuel cells. In this case the chemical energy difference between the two electrolytes physically separated by an electrode provides the voltage difference and current supplied by the batteries.

In general, all known cases of bipolar electrochemistry have two terminal external electrodes in place, and hence can be designated as “electrolytic” bipolar electrochemical processes.

In closed bipolar electrochemistry the potential across the substrate is equal to the potential applied across the feeder electrodes, and electrochemistry will occur on the isolated substrate at relatively low field intensities.

In contrast, in open bipolar electrochemistry the applied electrical field must reach a minimum value, which is relatively large, before the onset of bipolar electrochemistry on the isolated substrate.

In conclusion, all available electrochemical deposition techniques in prior art as described above, in particular the use of bipolar electrodeposition or electroless deposition by galvanic displacement, still have drawbacks and limitations among others being self-limitation and low yield.

### SUMMARY OF THE INVENTION

According to preferred embodiments it is an aim to provide bipolar electroless processing methods, which do not present the drawbacks of the prior art techniques.

In particular, it is an aim to achieve a non-limiting and high-yield electrochemical deposition technique.

A preferred aim according to preferred embodiments is to provide a high-yield selective deposition of metallic compounds onto the front side of a substrate.

Another aim according to preferred embodiments is to provide further control of the anodic and cathodic half reaction of the electrochemical deposition techniques.

According to preferred embodiments a bipolar “electroless” electrochemical process that solves the problems (low yield and self-limiting reactions) of existing electroless processes by galvanic displacement is disclosed. It is different from the above “electrolytic” bipolar electrochemical processing as it does not need external feeder electrodes to separate the oxidation (anodic) and reduction (cathodic) half reactions.

The bipolar electroless electrochemical processes according to preferred embodiments refer to processes such as deposition, electro etching and surface modification reactions in general wherein galvanic displacement reactions (oxidation-reduction half reactions) are involved to achieve the desired electrochemical process.

In the following paragraphs reference is made to bipolar open-circuit deposition (Bi-OCD) but the method is applicable to all bipolar open-circuit processes (Bi-OCP) in general, except the fact that the polarity of the used processes may change (e.g. anodic at the front side of the substrate for electro-etching or anodic at the back side of the substrate for deposition).

According to preferred embodiments a method is provided, referred to as photo Bi-OCD, for electroless deposition of metallic compounds onto the top surface of a semiconducting substrate comprising the following consecutive steps of:

providing a semiconducting substrate having a first (e.g. front) side (surface) of the substrate and a second (e.g. back) side (surface) of the substrate preferably opposite to the first side of the substrate thereby defining a thickness of semiconductor material,

contacting the first side of the substrate with a first electrically conductive electrolyte comprising dissolved metal ions of the metallic compound,

contacting the second side of the substrate with a second electrically conductive electrolyte,

providing an electrical conductive path between the first and second electrolytes.

The metallic compound comprises at least one metal or one metal alloy.

According to preferred embodiments, the metal compound can also comprise an alloy comprising more than one metal element.

Alloys can be classified by the number of their metal constituents. An alloy with two metal components is called a binary alloy; one with three metal components is a ternary alloy.

Two or more metal elements can be “co-deposited” in a method according to preferred embodiments.

According to preferred embodiments, the term “co-deposition” means that two or more metal elements are deposited at a same time, from a same bath leading to an alloy.

Different aspects and types of “co-deposition” are known in state of the art and described e.g. by Brenner et al. in “Electrodeposition of Alloys”, Academic Press, New York, 1963.

The alloy composition can be controlled by adjusting the bath composition (e.g. by changing the metal ion concentration), by adding completing agents to bring the standard potentials closer together and/or using different deposition parameters (potential or current).

Preferably, the first side of the substrate is the processing front side, i.e. the side where the deposition occurs.

The conductive electrolyte is a state of the art chemical solution comprising dissolved metal ions to produce an electrically conductive medium (Modern Electroplating (4^{th} edition), M. Schlesinger and M. Paunovic (editors), Wiley, New York, 2000).

Preferably, the first and the second electrolytes are the same.

Preferred embodiments herein are based on the surprising observation that carrying out a method according to preferred embodiments, comprising the differential illumination of the first side of the substrate versus the second side of the substrate, results in providing a driving force separating the cathodic and anodic partial reactions, starting a bipolar photo-electroless deposition and leading to high yield deposition of the metallic compound. The high yield process to be interpreted as a process with more than 90% yield, more preferably more than 95% and most preferred a process with approximately 100% yield.

The differential illumination is characterized by the fact that one side of the substrate (being the front side or the back side of the substrate) is more illuminated than the other side of the substrate (being the back side or the front side, respectively).

Preferably, the intensity of the illumination of the higher illuminated side of the substrate is at least 50% higher than the intensity of the illumination of the lower illuminated side of the substrate, more preferably the intensity of the illumination of the higher illuminated side of the substrate is 100% higher than the intensity of the illumination of the lower illuminated side of the substrate.

Preferably, a factor higher than 10⁴ and more preferably higher than 1 between the intensity of illumination of the higher and lower illuminated sides is required.

Preferably, a differential illumination of the front side of the substrate versus the back side of the substrate is applied such that a driving force is created to separate the anodic (oxidation) and cathodic (reduction) partial reactions.

Preferably, the illuminance of the higher illuminated side of the substrate is higher than 10⁵ lux (lumen per square meter) and more preferably ranges between 10⁵ to 10⁹ lux.

Preferably, the illuminance of the lower illuminated side of the substrate is lower than 0.5 lux (lumen per square meter) and more preferably ranges between 10⁻⁵ to 0.1 lux.

Preferably, the illumination is carried out by natural, visible light up to UV light depending on the type of substrate, and his corresponding bandgap, used.

The wavelengths of the illumination preferably range between 100 nm and 700 nm, more preferably between 300 nm and 700 nm.

The illumination can comprise a spectrum of wavelengths.

Monochromatic light can also be used in preferred embodiments.

The oxidation-reduction half reactions are space separated on the front side of the substrate versus the back side of the substrate, such that the reduction half reaction or deposition occurs at the front side of the substrate and the oxidation half reaction occurs at the back side of the substrate.

The photo Bi-OCD process according to preferred embodiments can be used to deposit metallic nanoparticles onto a substrate. By choosing an appropriate pattern onto the substrate, the metallic nanoparticles can be selectively deposited onto the substrate. The pattern can be a permanent pattern or a sacrificial pattern which can be removed in further processing steps.

The photo Bi-OCD process according to preferred embodiments can be used for the selective catalyst placement on semiconducting substrates to be used for growth and integration of nanowires (NW) or carbon nanotubes (CNT).

According to a preferred embodiment, the back side of the semiconducting substrate is more illuminated than its front side (the front side being at the same time possibly exposed to natural light of the ambient), in case the substrate is an n-type semiconducting substrate.

According to another preferred embodiment, the front side of the semiconducting substrate is more illuminated than its back side (the back side being at the same time possibly exposed to natural light of the ambient), in case the substrate is a p-type semiconducting substrate.

In case the substrate is a p-type semiconducting substrate, higher illumination is performed on the front side of the substrate to perform cathodic processing on the front side of the substrate (e.g. electrodeposition) and higher illumination is performed on the back side of the substrate to perform anodic processing on the front side of the substrate (e.g. electro etching).

In case the substrate is an n-type semiconducting substrate, the higher illumination is performed on the back side of the substrate to perform cathodic processing on the front side of the substrate (e.g. electrodeposition) and higher illumination is performed on the front side of the substrate to perform anodic processing on the front side of the substrate (e.g. electro etching).

As a preferred aspect, the method according to preferred embodiments related to a bipolar photo-electrochemical process for selective electroless processing such as the deposition of a metallic compound onto the top surface of a substrate, electro etching, electro polishing or substrate modification.

More preferably, according to preferred embodiments, a selective photo Bi-OCD is performed where, prior to the steps of contacting the substrate to an electrically conductive electrolyte, a layer is provided defining a pattern on the substrate wherein e.g. openings (pores) are created to form the pattern.

The pores or openings are not covered by the layer defining the pattern. As such, a direct contact between the metal deposited ions and the top surface of the substrate can occur.

Preferably the pattern is made of an insulating material to avoid electroless processing.

According to a preferred embodiment, the front side (top surface) of the substrate is at least partly covered with an insulating pattern whereby the deposition of the metallic compound takes place selectively into the openings not covered by the pattern.

Alternatively a metallic pattern can be first deposited onto the substrate such that the reduction half reaction or deposition occurs on the substrate inside the openings of the pattern and the oxidation half reaction occurs on the metal pattern itself (acting as anode) or vice versa.

The metallic pattern can be a permanent or sacrificial pattern which can be removed or covered up in further processing.

According to another preferred embodiment, the top surface of the substrate is at least partly covered with a metal comprising pattern such that the deposition of the metallic compound takes place selectively onto the surface of the pattern in case the substrate is an n-type semiconducting substrate.

According to yet another preferred embodiment, the top surface of the substrate is at least partly covered with a metal comprising pattern such that the deposition of the metallic compound takes place selectively into the openings of the pattern in case the substrate is a p-type semiconducting substrate.

More preferably, in case the substrate is an n-type semiconducting substrate the substrate is selected from at least one of Si, Ge, GaAs doped with a group III element.

Preferably, the group III element is B, Al, Ga, In or Tl.

More preferably, in case the substrate is a p-type semiconducting substrate the substrate is selected from at least one of Si, Ge, GaAs doped with a group V element.

Preferably, the group V element is N, P, As, Sb or Bi.

Alternatively and also preferred, the substrate is a light sensitive metal oxide such as In₂O₃, TiO₂ or SnO₂.

In an alternative and also preferred embodiment a bipolar photo-electrochemical (photo Bi-OCD) process for selective electroless deposition is disclosed whereby the substrate is made of a semiconducting material (e.g. Si) and the pattern used to cover at least partly the front side of the substrate is made of a metallic compound. In this alternative and preferred embodiment, both oxidation and reduction (deposition) reactions take place at the front side of the substrate but separated by metal/semiconductor regions. Differential illumination is used to create a potential difference and the electrolyte solution makes contact with the front side of the substrate only (the back side of the substrate remains dry). For metal (alloy) deposition by the photo Bi-OCD process on the semiconductor substrate regions (i.e. semiconductor as cathode and metal as anode), the semiconductor substrate needs to be p-type and preferably the front side of the substrate is higher illuminated. For metal (alloy) deposition by the photo Bi-OCD process on the metallic regions (i.e. metal as cathode and semiconductor as anode), the front side of the substrate is higher illuminated and the substrate is an n-type semiconducting substrate. Further, the metallic regions are preferably inert to the dissolution (e.g. Ta, TaN, Ti, TiN, Pt).

In yet another alternative and also preferred embodiment a bipolar photo-electrochemical (photo Bi-OCD) process is disclosed whereby the semiconducting substrate is partly covered by metallic regions and the semiconducting regions are covered with an insulating pattern with openings exposing the semiconductor to the electrolyte. For a p-type semiconducting substrate, the exposed metallic regions will act as the anode and the exposed semiconductor as cathode upon illumination (preferably higher front illumination) leading to metal deposition by photo Bi-OCD on the semiconducting substrate. For an n-type semiconducting substrate, the exposed metallic regions will act as the cathode anode and the exposed semiconductor as anode upon illumination leading to electro-etching.

Examples of preferred semiconducting materials are group IV semiconductors, such as silicon (Si) and germanium (Ge), III-V semiconductors, such as GaAs, GaP, GaSb, InP, InSb, InAs and II-VI semiconductors such as ZnO, ZnS, CdS and CdSe. In case a semiconductor material (e.g. silicon) is used as substrate, the (silicon) substrate is preferably doped e.g. with group III elements (B, Al, Ga, In, Tl) causing the substrate (silicon) to function as an electron acceptor or in other words as a p-type substrate. Alternatively, the semiconductor material (e.g. silicon) is doped with group V elements (N, P, As, Sb, Bi) causing the substrate silicon to act as an electron donor or in other words as an n-type substrate. Therefore, a silicon substrate doped with boron creates a p-type semiconductor whereas one doped with phosphorus results in an n-type material. Another preferred example of a substrate is a GaAs consisting/containing material.

Alternatively light sensitive metal oxides can be used as substrate; preferred examples of these light sensitive metal oxides are In₂O₃, TiO₂ and SnO₂.

In case selective photo Bi-OCD is performed, a layer is deposited onto the front side of the substrate into which openings or pores are present and/or need to be created to form a pattern.

In a preferred embodiment the deposited layer is made of an insulating material or dielectric to avoid electrochemical deposition onto the surface of the layer.

Examples of the layer are oxides such as SiO₂ and alumina (aluminum oxide), nitrides such as Si₃N₅, carbides such as SiC, organic polymeric materials such as PMMA (polymethyl methacrylate) resists, low-k dielectric materials, zeolites such as silicates and porous oxides such as Anodized Alumina Oxide (AAO).

A SiO₂ layer can be deposited e.g. by Chemical Vapor Deposition (CVD) techniques.

In an alternative and also preferred embodiment the deposited layer is made of a metallic compound such as Ti, TiN, TaN, Ta, Al, Cr, Pb, and the like. However in this alternative and preferred embodiment, both oxidation and deposition reactions may take place at the front side of the substrate but separated by metal/semiconductor.

Under illumination metal deposition (reduction) will occur in the semiconductor openings in case of a p-type semiconductor substrate and on the metal pattern in case of an n-type semiconducting substrate. The oxidation reaction will occur on the metallic pattern in case of a p-type substrate and in the semiconductor openings in case of an n-type semiconducting substrate.

In an alternative and also preferred embodiment, an insulating micro pattern may cover the macro patterned semiconductor and/or metallic regions. For example a rectangular area or box (e.g. 10 μm×10 μm) of a p-type Si substrate is covered with a patterned SiO₂ with circular holes of 50 nm in diameter and a pitch of 100 nm exposing the p-site. This box is surrounded by a metal line (e.g. 500 nm wide TiN) on the Si substrate, forming a square around the Si/SiO₂ box.

Using the insulating pattern in the electroless photo Bi-OCD according to preferred embodiments, the cathodic half reaction (reductive deposition) is confined to certain areas or holes i.e. limiting the place of deposition (referred to as “selective deposition”) inside the holes of the pattern.

Preferably the openings (pores) in the deposited layer have a diameter of 1 nm up to several μm depending on the application. The openings are such that no insulating material is left at the bottom of the opening. The depth of the opening can range from 10 nm up to 500 nm depending on the application.

In case the deposited layer is made of a porous material such as zeolites or anodized alumina oxide (AAO), no patterning step is needed (but may be still used) to form pores (a pattern). The pores are instead formed by self-assembly.

Porous alumina (or AAO) can be formed on a substrate, such as silicon by iodization of an aluminum film deposited e.g. by means of Physical Vapor Deposition. This porous film can be from a few nanometers up to several microns thick.

Preferably, the front side of the substrate (comprising the pattern) is contacted to a first electrically conductive electrolyte comprising dissolved metal ions of the metallic compound to be deposited.

Preferably, the dissolved metal ions in the first electrically conductive electrolyte are capable of forming cathodic reactions on the front side of the substrate such that photo Bi-OCD of these metals onto the front side of the substrate is possible (inside openings in the dielectric or pores).

Preferred examples of these metal ions are Ni²⁺, Co²⁺, Cu²⁺, In³⁺, Au⁺, Au³⁺, Fe²⁺, Fe³⁺, Pt²⁺, Pd²⁺, Pb²⁺, Sb³⁺, Bi³, Zn²⁺, Ga³⁺, Ge⁴⁺, R³⁺, R²⁺ and inorganic and organic complexes thereof, but the method according to preferred embodiments is not limited to these metals and can be applied to basically any material that can be electrodeposited, including alloys of these metals and in combination with W, Mo, V, Cr, Mn.

Preferred concentrations of the metals in the first electrically conductive electrolyte are in the range of 1 mM up to 1M depending on the application.

Other ions added to the first electrically conductive electrolyte for complexation and improved conductivity are e.g. OH⁻, F⁻, Cl⁻, I⁻, Br⁻, NO₃⁻, SO₄²⁻, PO₄³⁻, S₂O₃²⁻, SO₃²⁻, sulfa mate-, flu borate-, borate-, cyanide-, fluoride- as anions and Na⁺, K⁺, Ca²⁺, Al³⁺, Mg²⁺, Li⁺, NH₄⁺, H⁺ as counter cations, with the total charge of anions and cations (including the metal ions) making a balance of zero.

Preferred concentrations of the salts in the first electrically conductive electrolyte are in the range of 1 mM up to 6M depending on the application.

The electrolyte compositions are not limited to the above mentioned, and combinations are unlimited. For examples of recipes for typical plating electrolyte compositions is referred to literature.

The method according to preferred embodiments can also be extended to electrochemical processing in general such as electro etching or surface modification.

Preferably, the back side of the substrate is contacted to a second electrically conductive electrolyte. In this case, the substrate is separating the first and second electrolytes and we refer to “closed” photo Bi-OCD. The separation can be made by mounting the substrate in-between two cells which have an opening sealed by the substrate (front side of the substrate seals the cell with electrolyte 1 and the back side of the substrate seals the cell with electrolyte 2). For fast loading and unloading of the substrate (wafer), a quick load/unload substrate (wafer) mount can be used which can contain one electrolyte and gets submerged in the second electrolyte or vice versa.

In case the substrate is a silicon containing substrate, the second electrically conductive electrolyte can contain HF or other fluoride containing compounds such as NH₄F, HBF₄ and combinations thereof (e.g. buffered HF) to avoid deposition of SiO₂ onto the back side of the substrate.

Preferred examples, but not limited to, of the second electrolyte are e.g. OH⁻, Cl⁻, NO³⁻, SO₄²⁻, PO₄³⁻, S₂O₃²⁻, SO₃²⁻, I⁻, I₃⁻, IO₃⁻, Br⁻, BrO₃⁻, sulfamate, fluoborate, borate, fluoride based solutions and mixtures thereof with counter cations of Na⁺, K⁺, Ca²⁺, Al³⁺, Li⁺, NH₄⁺, H⁺ (making the total ion balance=0).

Preferred concentrations of the salts in the second electrolyte are in the range of 1 mM up to 6M depending on the application.

Alternatively and also preferred, the substrate is fully immersed in the first electrically conductive electrolyte. In this case it is referred to as “open” photo Bi-OCD or open photo Bi-OCP and the anodic and cathodic reactions occur in the same electrolyte.

Alternatively and also preferred, only the front side of the substrate is immersed in the first electrically conductive electrolyte and the dry back side of the substrate is illuminated.

In case two electrolytes are needed, the first and second electrically conductive electrolytes are connected to each other by forming an electrical conductive path between the first and second electrolytes.

The electrical conductive path can be created by means of a salt bridge or alternatively by means of external electrodes immersed in both electrolytes.

The closed photo Bi-OCD process starts as soon as the electrolytic contact is made between the two electrolytes.

In a preferred embodiment to perform selective photo Bi-OCD, light is used to create a potential difference between the front side of the substrate and the back side of the substrate and whereby the substrate is made of a semiconducting material (e.g. Si) and the pattern (if present) used to cover at least partly the front side of the substrate is made of an insulating material (to avoid deposition onto the pattern). In case an n-type semiconducting substrate is used, the back side of the substrate is more illuminated than the front side of the substrate. In case a p-type semiconducting substrate is used, the front side of the substrate is more illuminated than the back side of the substrate.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1 (PRIOR ART) illustrates the metallic deposition in a pattern using unipolar OCD where both the front and back side of the substrate are exposed to light of the working environment.

FIG. 2 illustrates the different processing steps according to preferred embodiments to use bipolar photo-OCD to deposit a thick metallic layer on the top surface of an n-type substrate with more illumination on the back side of the substrate than on the front side of the substrate.

FIG. 3 illustrates the different processing steps according to preferred embodiments to use bipolar photo-OCD to deposit a thick metallic layer on the top surface of a p-type substrate with more illumination on the front side of the substrate than on the back side of the substrate.

FIG. 4 illustrates the different processing steps according to preferred embodiments to use bipolar photo-OCD to deposit a metallic compound into the inner pore openings of an insulating pattern situated on the top surface of an n-type substrate with more illumination on the back side of the substrate than on the front side of the substrate.

FIG. 5 illustrates the different processing steps according to preferred embodiments to use bipolar photo-OCD to deposit a metallic compound into the inner pore openings of a metallic pattern situated on the top surface of a p-type substrate with more illumination on the front side of the substrate than on the back side of the substrate.

FIG. 6 illustrates the different processing steps according to preferred embodiments to use bipolar photo-OCD to deposit a metallic compound onto the metallic pattern situated on the top surface of an n-type substrate with more illumination on the front side of the substrate than on the back side of the substrate.

FIG. 7 illustrates the different processing steps according to preferred embodiments to use bipolar photo-OCD to deposit a metallic compound into the inner pores of the insulating pattern situated on the top surface of a p-type substrate with more illumination on the front side of the substrate than on the back side of the substrate and wherein the top surface of the substrate further comprises a patterned metallic structure acting as anode.

FIG. 8 illustrates a bipolar electrochemical set-up with two electrolyte baths using a salt bridge.

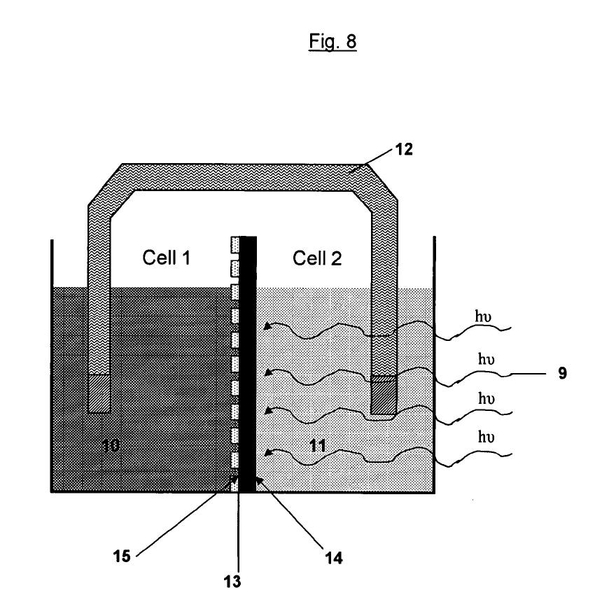

FIG. 9 illustrates the band structure of the bipolar electrode. FIG. 4A shows the electronic energy levels of a p-type substrate with higher illumination on the front side cathode of the substrate and FIG. 4B shows the electronic energy levels of a bipolar n-type substrate with higher illumination on the back side anode of the substrate.

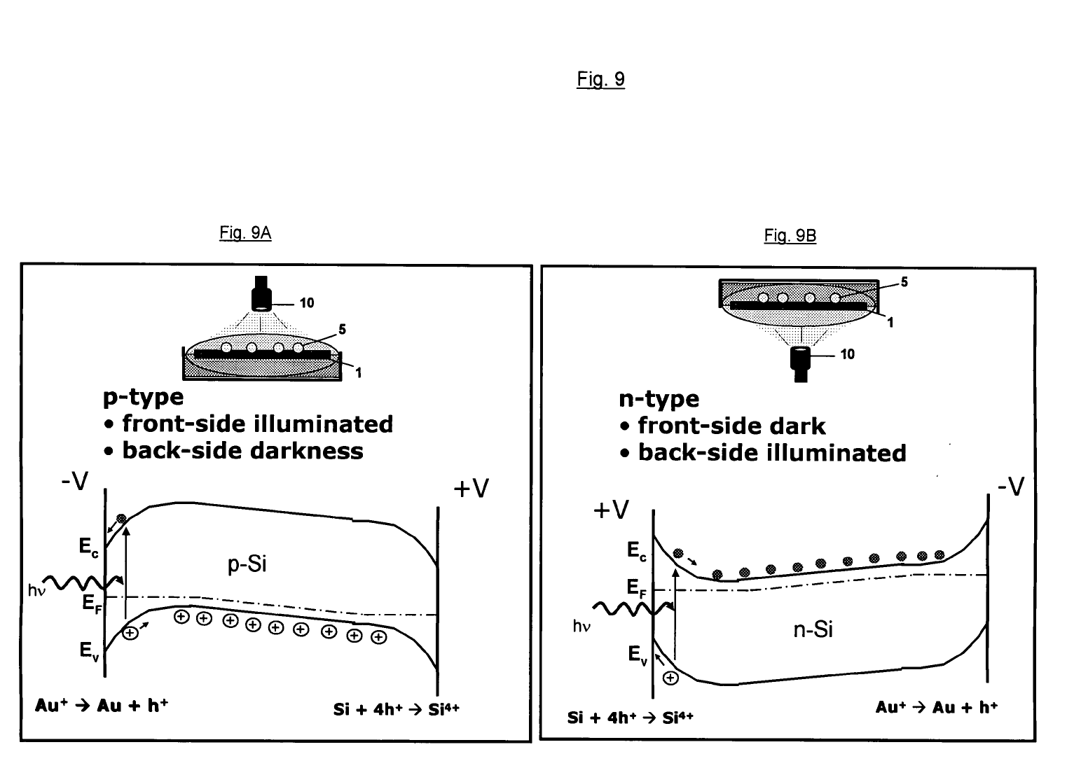

FIG. 10 illustrates the selective photo-electroless Bi-OCD for gold (Au) deposition in patterned holes on SiO₂ in a dielectric layer on a p-type Si (100) substrate. The electrolyte used was 10 mM Au(I) S₂O₃/SO₃ solution at room temperature and pH=7.

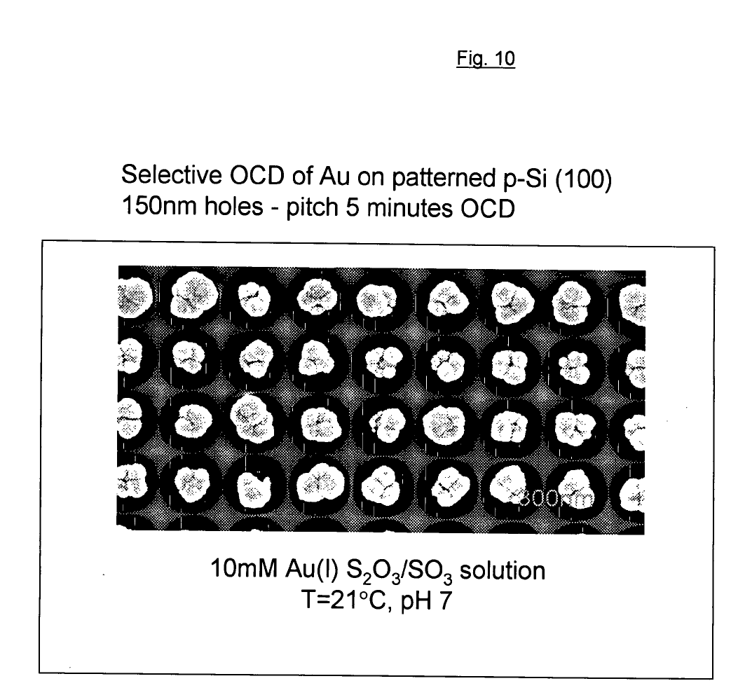

FIG. 11A illustrates (prior art) unipolar electroless electrochemical deposition compared to selective OCD (2-3 minutes OCD) as illustrated in FIG. 11B of Au into the inner pores of the insulating pattern (150 nm holes—pitch) on top surface of an n-type Si (100) substrate using a 10 mM electrolyte solution (pH=7).

### DETAILED DESCRIPTION OF THE PREFERRED EMBODIMENT

The above and other characteristics, features and advantages of preferred embodiments will become apparent from the following detailed description, taken in conjunction with the accompanying drawings, which illustrate, by way of example, the principles. This description is given for the sake of example only, without limiting the scope. The reference figures quoted below refer to the attached drawings.

### DEFINITIONS

The term “electrochemical processes” as used herein refer to both deposition processes and metal-removal processes (such as for example electro polishing, chemical etching and electro etching).

It is to be understood that the terms “electrochemical processes” and “electrochemical processing” are equivalent.

The word “deposition” herein means the act of depositing particles onto a surface of a substrate.

“Electrochemical processing” (ECP) and “electrochemical deposition” (ECD) as used herein refer to an electrolytic process which requires an external voltage and current.

“Open-circuit processing” (OCP) and “open-circuit deposition” (OCD) as used herein refer to electroless processing by galvanic displacement and electroless deposition by galvanic displacement respectively.

The respective bipolar processes as used are bipolar electrochemical processing (Bi-ECP), bipolar electrochemical deposition (Bi-ECD), bipolar open-circuit processing (Bi-OCP) and bipolar open-circuit deposition (Bi-OCD).

The expression “electroless Bi-OCD” is a “photo Bi-OCD” process whereby light is used as a driving force to create the potential difference (i.e. photo voltage) between the front side of the substrate and the back side of the substrate.

It is to be understood that the terms “electroless Bi-OCD”, “photo Bi-OCD”, “bipolar photo-OCD” and “photo-electroless Bi-OCD” are equivalent.

The term “selective deposition” onto a substrate as used refers to the deposition of a compound on a predetermined specific area of a substrate and not on the whole substrate area.

It is to be understood that the terms “electrochemical deposition” and “plating” are equivalent.

“Electroplating” as used is the process of using electrical current to coat an electrically conductive object with a relatively thin layer of metal. “Electroless plating” means a non-galvanic type of plating method that involves several simultaneous reactions in an aqueous solution, which occur without the use of external electrical power.

The term “nanoparticle” as used is a particle having a diameter which is preferably less than 100 nm.

The term “catalyst” as used is a substance that accelerates the chemical reaction.

Particular embodiments will be described below with reference to certain drawings but this is not intended to limit it thereto but only by the scope of the appended claims. The drawings described are only schematic and are non-limiting. In the drawings, the size of some of the elements may be exaggerated and not drawn to scale for illustrative purposes. The dimensions and the relative dimensions do not correspond to actual reductions to practice.

Preferred embodiments will now be described by a detailed description. It is clear that other embodiments can be configured according to the knowledge of persons skilled in the art without departing from the true spirit or technical teaching, being limited only by the terms of the appended claims.

In particular, preferred embodiments will be described with reference to the (selective) deposition of metallic compounds (e.g. nanoparticles for use a catalyst in nanowire or carbon nanotube growth), however, this is not intended to limit, and is only one example of an application to perform the method of bipolar electrochemical processes.

It is appreciated to consider all electrochemical processes such as electro etching, electro polishing and surface modification as being part of the application as well.

In the following detailed description reference is made to Bi-OCD but the method is applicable to all Bi-OCP processes in general, except the fact that the polarity of the processes may change (e.g. anodic at the front side of the substrate for electro-etching).

Preferred embodiments disclose novel bipolar open-circuit processes (Bi-OCP) and bipolar open-circuit deposition (Bi-OCD) methods which makes use of light (illumination) to create a potential difference. The novel bipolar processes are referred to as “photo Bi-OCP” and respectively “photo Bi-OCD”.

A bipolar open-circuit deposition (Bi-OCD) process is disclosed for deposition of metallic compounds (pure metals or metal alloys) onto a substrate. By separating the oxidation-reduction half reactions a large and inexhaustible anode surface can be provided and the deposition process is free of surface oxide and not self-limiting leading to a high yield and unlimited thickness control.

The photo Bi-OCD process according to preferred embodiments can be used for the selective catalyst placement on semiconducting substrates to be used for growth and integration of nanowires (NW) or carbon nanotubes (CNT).

It is an advantage of the photo Bi-OCD process according to preferred embodiments to use Si based materials and process knowledge to realize the selective catalyst placement. The method can be easily processed and incorporated in current Si-based technology devices.

It is further an advantage of the photo Bi-OCD process according to preferred embodiment to avoid the need for a back contact (to be used as electrical terminal) onto the substrate. In many applications, direct contact to the substrate needs to be avoided to eliminate back side contamination. Using the method according to preferred embodiments makes the use of (a) direct contact point(s) to the substrate needless and also other remedies such as implantation and/or metallization of the back side of the substrate are needless. Using the method according to preferred embodiments makes it possible to use the electrolyte(s) as an electrical contact in which the substrate is acting as a bipolar electrode.

Preferred embodiments solve the problem of selective deposition of metallic compounds (pure metals or metal alloys) onto the front side of a substrate with high yield using a photo Bi-OCD process. The problem is solved first by covering the front side of the substrate with an insulating pattern such that the deposition of the metallic compound takes place selectively into the openings (pores) of the pattern and secondly by differential illumination of the front side of the substrate versus the back side of the substrate to provide a driving force to separate the cathodic and anodic partial reactions. More specifically, light is used to create a potential difference or photo voltage between the higher illuminated and lower illuminated areas. The photo Bi-OCD according to preferred embodiments is further characterized as a bottom up electrochemical deposition process with high yield capable of filling very narrow pores (openings). The openings can be in the nanometer range up to the micrometer range such that the method is suitable for use as catalyst placement for carbon nanotube (CNT) or nanowire (NW) growth as well as for through-hole plating processes where no physical contact can be made with the substrate.

The problem of controlling the anodic and cathodic half reaction during electroless electrochemical processes such that the process becomes not self-limiting and a continuous process can be achieved with high yield is solved. In case the electroless electrochemical process is a deposition (plating) process a continuous deposition of the compound of interest is achieved leading to thick deposits.

Thus, using the photo Bi-OCD according to preferred embodiments makes it possible to deposit the metallic compound of interest inside the pattern with high yield, compared to a standard electroless electrochemical deposition (OCD) having poor control of the cathodic and anodic reactions and giving rise to low yield.

By using a preferred embodiment of the bipolar electroless approach according to preferred embodiments, the anodic and cathodic half reactions are separated using the back side of the substrate as a large inexhaustible anode surface.

Preferred embodiments disclose further the use of more light or higher illumination of the back side (or alternatively of the front side) of the substrate to create a potential difference.

Preferred embodiments are now described in more detail. Summarized a photo bipolar open-circuit process (photo Bi-OCP) is disclosed whereby a substrate having at least a front side of the substrate and a back side of the substrate is in contact with at least one electrolyte and the photo Bi-OCP process is performed onto the front side of the substrate using higher illumination of the back side (alternatively front side) of the substrate to achieve a potential difference.

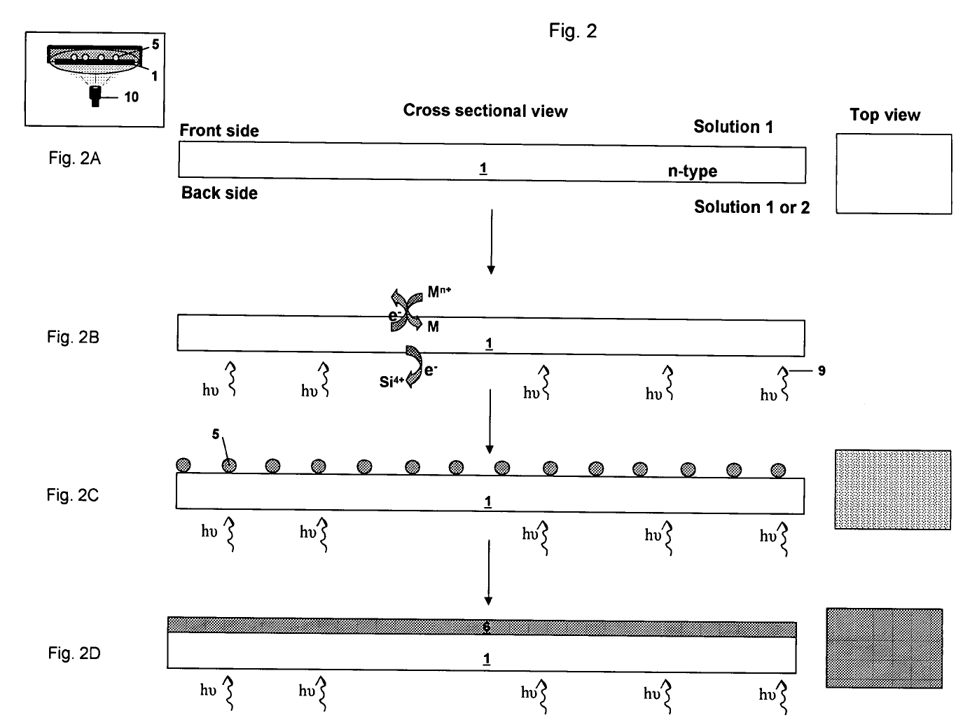

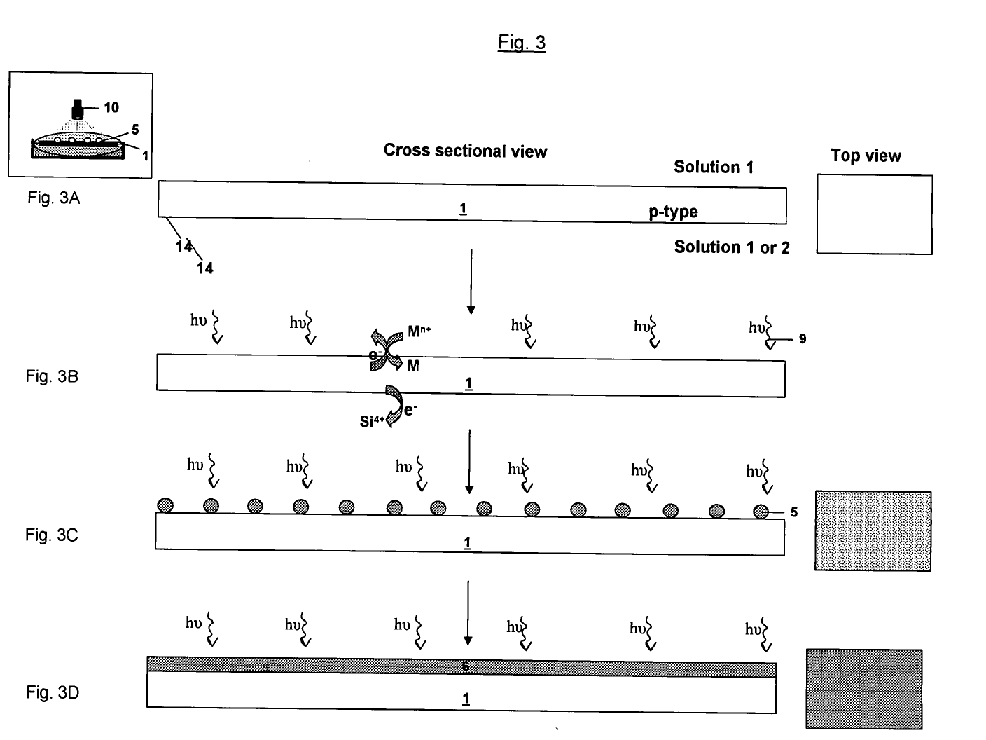

According to preferred embodiments, a photo bipolar open-circuit deposition (photo Bi-OCD) method for depositing a metallic layer (pure metal or alloy of metals) onto a substrate is illustrated in FIG. 2 for an n-type substrate and in FIG. 3 for a p-type substrate. The method starts with the step of first providing a substrate 1. Most preferred the substrate 1 is made of a p-type (or alternatively an n-type) semiconducting material and/or a light sensitive (metal) oxide and/or a semiconducting polymer.

Examples of preferred semiconducting materials are silicon (Si) and germanium (Ge). In case a semiconductor material (e.g. silicon) is used as substrate, the (silicon) substrate is preferably doped e.g. with group III elements (B, Al, Ga, In, Tl) causing the substrate (silicon) to function as an electron acceptor or in other words as a p-type substrate. Alternatively, the semiconductor material (e.g. silicon) is doped with group V elements (N, P, As, Sb, Bi) causing the substrate silicon to act as an electron donor or in other words as an n-type substrate. Therefore, a silicon substrate doped with boron creates a p-type semiconductor whereas one doped with phosphorus results in an n-type material. Another preferred example of a substrate is a GaAs consisting/containing material. Alternatively light sensitive metal oxides can be used as substrate; preferred examples of these light sensitive metal oxides are In₂O₃, TiO₂ and SnO₂.

In a next step, as illustrated in FIG. 2B (and FIG. 3B), the front side of the substrate is contacted to a first electrically conductive electrolyte comprising dissolved metal ions of the metallic compound to be deposited (indicated as solution 1).

Preferably, the dissolved metal ions (Mn⁺) in the first electrically conductive electrolyte are capable of forming cathodic reactions on the front side of the substrate such that photo Bi-OCP (deposition) of these metals onto the front side of the substrate is possible.

Preferred examples of these metals are Ni²⁺, Co²⁺, Cu²⁺, In³⁺, Au⁺, Fe²⁺, Fe³⁺, Pt²⁺, Pd²⁺, . . . but not limited to these metals and can be applied to basically anything that can be deposited.

Preferred concentrations of the metals in the first electrolyte are in the range of 1 mM up to 1M depending on the application.

Preferred examples of the first electrolyte are e.g. Cl—, NO₃⁻, SO₄²⁻, PO₄³⁻, S₂O₃²⁻, SO₃²⁻, sulfamate, fluoborate, borate, cyanide, fluoride based solutions and mixtures thereof with counter cations of Na⁺, K⁺, Ca²⁺, Al³⁺, Li⁺, NH₄⁺, H⁺ (making the total ion balance=0).

Preferred concentrations of the salts in the first electrolyte are in the range of 1 mM up to 6M depending on the application.

Preferably, the back side of the substrate is contacted to a second electrically conductive electrolyte (indicated as solution 2). The contact can be made by pressing the back side of the substrate to a porous path containing the second electrically conductive electrolyte or the contact can be clamped between two cells. In case the substrate is a silicon containing substrate, the second electrically conductive electrolyte can contain HF to avoid deposition of SiO₂ onto the back side of the substrate.

Preferred examples of the second electrolyte are e.g. Cl—, NO³⁻, SO₄²⁻, PO₄³⁻, S₂O₃²⁻, SO₃²⁻, sulfamate, fluoborate, borate, cyanide, fluoride based solutions and mixtures thereof with counter cations of Na⁺, K⁺, Ca²⁺, Al³⁺, Li⁺, NH₄⁺, H⁺ (making the total ion balance=0).

Preferred concentrations of the salts in the second electrolyte are in the range of 1 mM up to 6M depending on the application.

The first and second electrolyte can be identical such that only one electrolytic bath is required and the substrate can be immersed in the bath.

In case two different (non-identical) electrolytes are needed, the first and second electrically conductive electrolytes are connected to each other by forming an electrical conductive path between the first and second electrolytes.

The electrical conductive path can be created by means of a salt bridge or alternatively by means of external electrodes immersed in both electrolytes.

Preferably, light 9 is used to achieve the potential difference needed to achieve photo Bi-OCD or in other words light is used as a driving force to create the potential difference between the front side of the substrate_and the back side of the substrate. The light intensity of the incident light will determine the potential difference and the rate of reaction (more photo-electrons and photo holes available for reaction).

Natural, visible light up to UV light is used depending on the type of substrate, and his corresponding bandgap, used.

The wavelengths of the light range between 100 nm and 700 nm, preferably between 300 nm and 700 nm.

The light can contain a spectrum of wavelengths.

The light can be monochromatic light.

Examples of possible cathodic half reactions during the photo Bi-OCD process are:

Ni²⁺+2e→Ni

Co²⁺+2e→Co

Cu²⁺+2e→Cu

In³⁺+3e→In

Au⁺+e→Au

Examples of possible anodic half-reactions during photo Bi-OCD taking place at the back side of the substrate are:

Si+4h⁺+2H₂0→SiO₂⁻

Si+4h⁺+6F⁻→SiF₆²⁻ (in the presence of HF)

The above mentioned anodic and cathodic half reactions refer to displacement reactions with silicon (galvanic reaction) whereby silicon is oxidized and metal ions in solution are reduced and deposited onto the front side of the substrate. The cathodic half reaction is highly selective for silicon surface.

The metal is first deposited as small metal nanoparticles 5 as illustrated in FIG. 2C (or FIG. 3C) and subsequently (longer OCD time) as a continuous metallic film 6 as illustrated in FIG. 2D (or FIG. 3D).

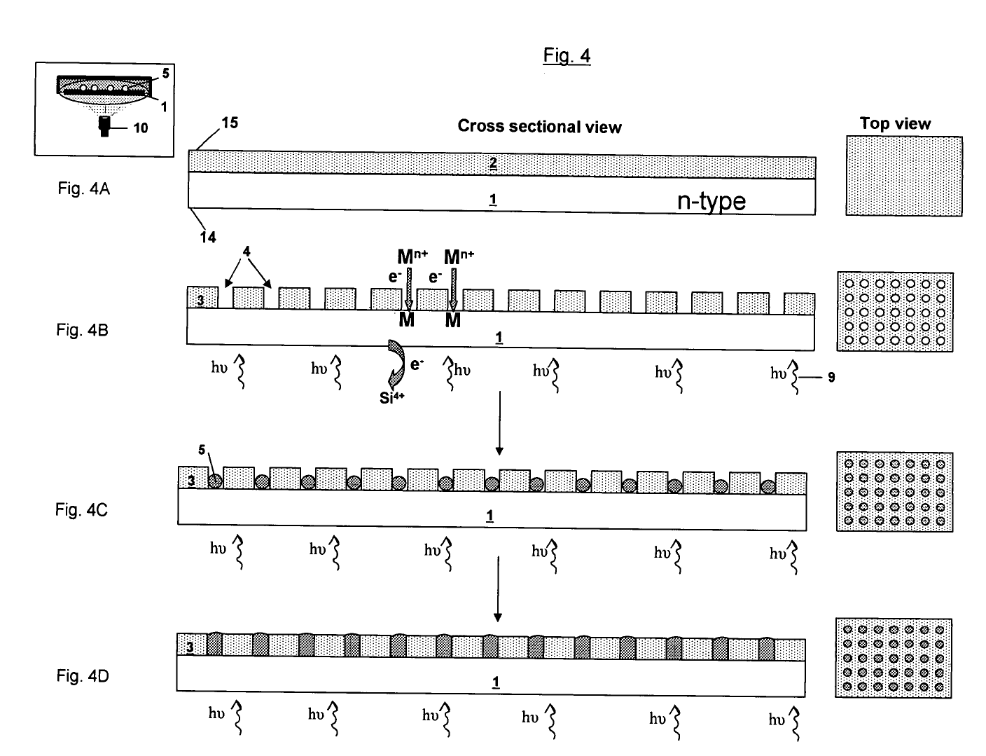

In a second preferred alternative of the first embodiment, a method for selective depositing a metallic compound (pure metal or alloy of metals) onto a substrate is disclosed and illustrated in FIG. 4 for an n-type substrate. The substrate is preferably selected from at least one of the preferred examples described above (according to the first preferred embodiment).

To achieve selective deposition of the metallic compound, the front side of the substrate 1 is partly covered with a pattern 3 to achieve selective electroless photo Bi-OCD.

Preferably the pattern is an insulating pattern such that no deposition of the metallic compound 5 results on the pattern 3 or in other words to avoid deposition onto the surface of the pattern 3.

The insulating pattern 3 can be created by first depositing a layer 2 onto the front side of the substrate 1 and subsequently (if needed) creating openings or pores 4 in the deposited layer to create a pattern. Preferably the openings (pores) 4 in the deposited layer have a diameter of 1 nm up to several μm depending on the application. The openings 4 are such that no insulating material is left at the bottom of the opening. The depth of the opening can range from 10 nm up to 500 nm depending on the application.

Preferably the deposited layer is made of an insulating material such as SiO₂ or organic polymeric materials.

A pattern (e.g. holes or pores but also lines or other shapes) can be created into the deposited layer by means of photolithographic patterning.

A SiO₂ layer can be deposited e.g. by Chemical Vapor Deposition techniques (CVD).

Alternatively and also preferred the deposited layer is made of a porous material such as zeolites or anodized alumina oxide (AAO) and no patterning step is needed to form pores (a pattern). The pores are instead formed by self-assembly.

Porous alumina (or AAO) can be formed on a substrate, such as silicon by anodization of an aluminum film deposited e.g. by means of Physical Vapor Deposition. This porous film can be from a few nanometers up to several microns thick.

After formation of the insulating pattern on the front side of the substrate differential illumination of the front side of the substrate versus the back side of the substrate is done to create a potential difference which separates the cathodic and anodic partial reactions.

In case the substrate is a p-type semiconducting substrate, the front side of the substrate is more illuminated 9 than the back side of the substrate and, in case the substrate is an n-type semiconducting substrate, the back side of the substrate is more illuminated 9 than the front side of the substrate. The metal is deposited into the pore openings as shown in FIG. 4C.

The metal is first deposited as small metal nanoparticles 5 as illustrated in FIG. 4C and if wanted the whole pattern (openings or holes) can be filled up with the metallic compound as illustrated in FIG. 4D. The metal deposition continues with time until light is switched off.

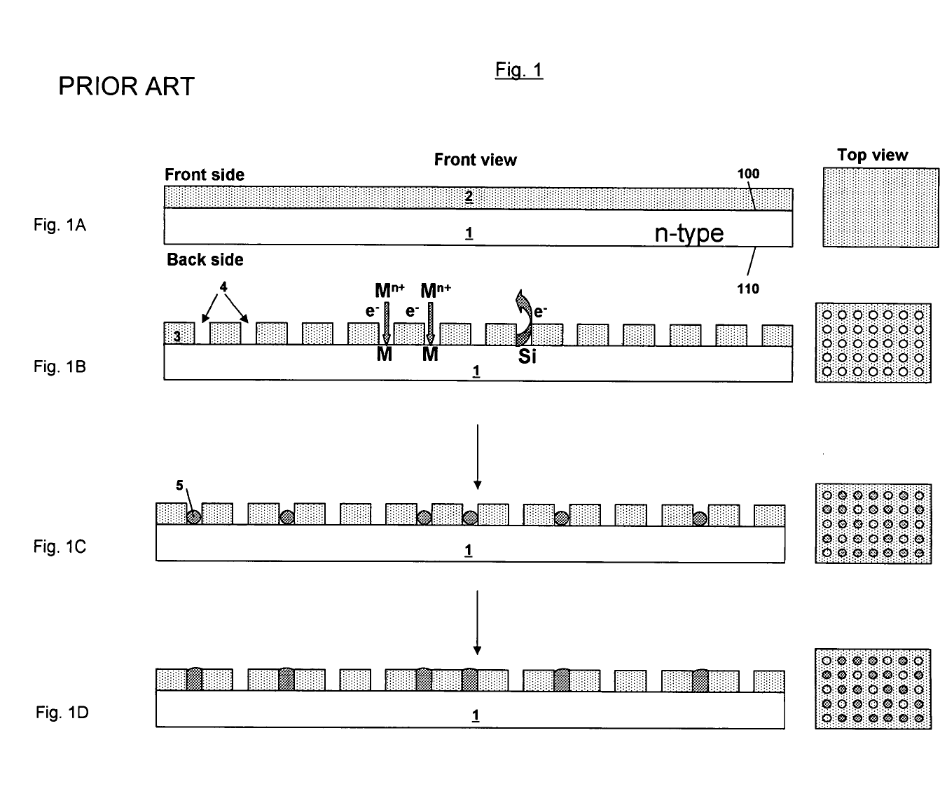

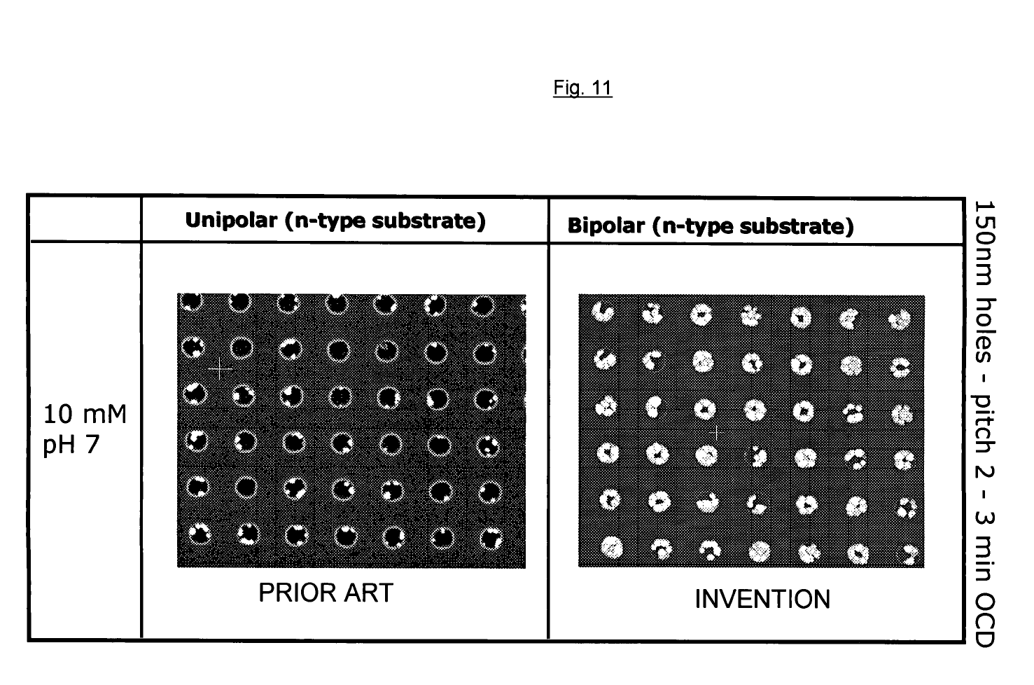

Using the photo Bi-OCD according to preferred embodiments makes it possible to deposit the metallic compound of interest inside the pattern with high yield, compared to standard electroless electrochemical plating having poor control of the cathodic and anodic reactions and giving rise to low yield as illustrated in FIG. 1 and FIG. 11A.

FIG. 11A illustrates (prior art) unipolar electroless electrochemical deposition compared to selective OCD (2-3 minutes OCD) as illustrated in FIG. 11B of Au into the inner pores of the insulating pattern (150 nm holes—pitch) on top surface of an n-type Si (100) substrate using a 10 mM electrolyte solution (pH=7). It is noticed from these 2 figures that the yield of the selective OCD (illustrated in FIG. 11B) compared to the yield of the prior art unipolar electroless electrochemical deposition (FIG. 11A) is at least doubled.

Full illumination is needed to achieve good uniformity of deposition.

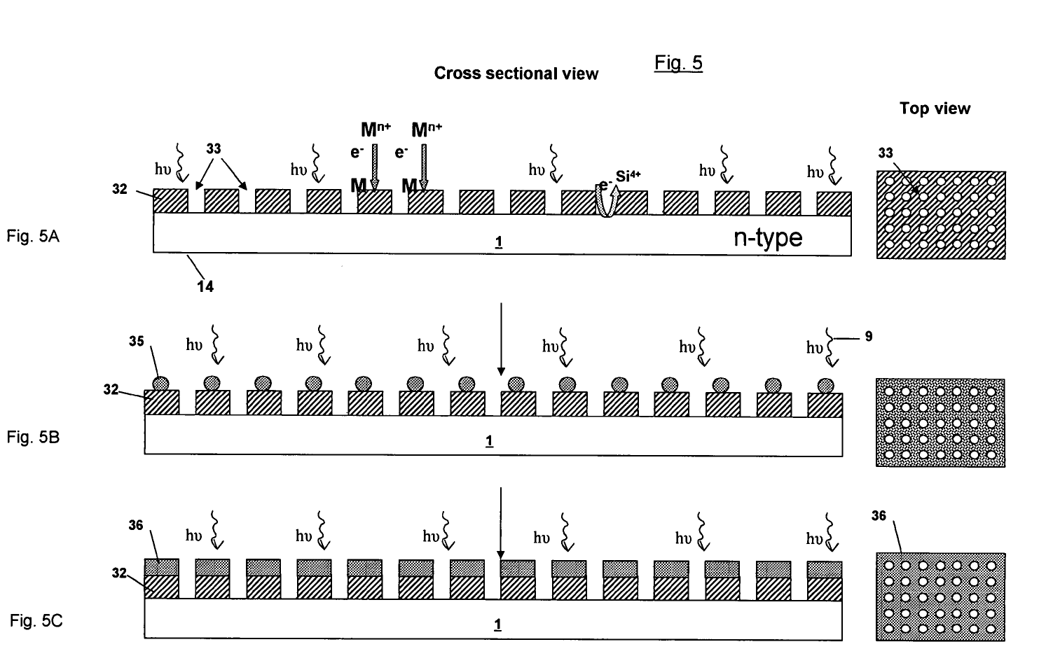

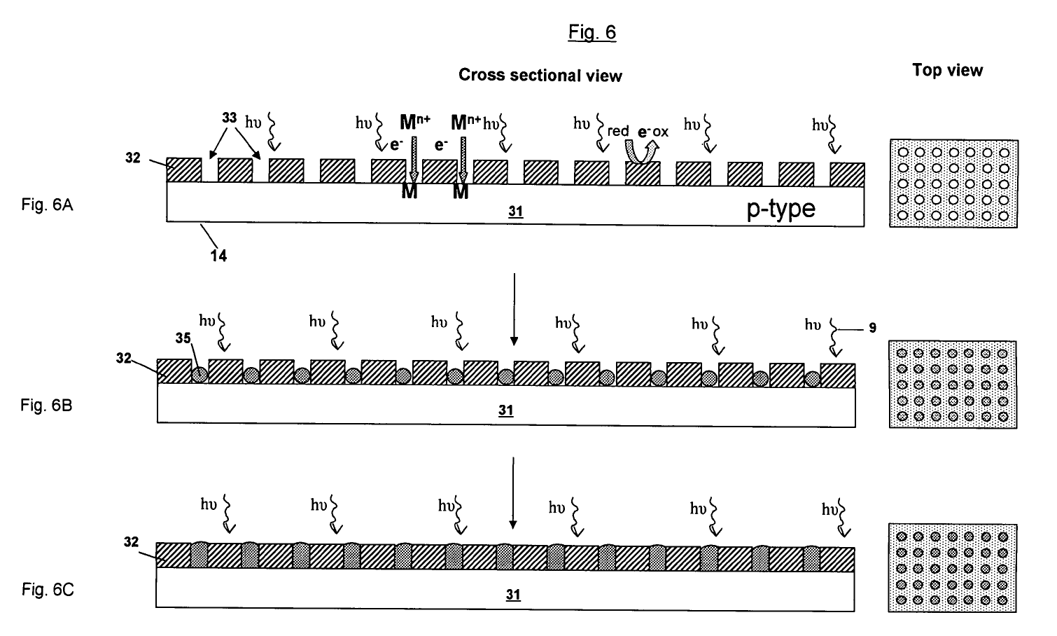

In a third and also preferred alternative of the above described embodiments as shown in FIG. 5 and FIG. 6 the deposited layer to create a pattern on the front side of the substrate is made of a metallic compound. The substrate is preferably selected from at least one of the preferred examples described above (according to the first preferred embodiment). However in this alternative and preferred embodiment, both oxidation and deposition reactions take place at the front side of the substrate but separated by metal/semiconductor regions having deposition on the metallic regions or alternatively onto the metallic pattern (using the metallic pattern as anode).

Using the metallic pattern onto a p-type substrate in the photo Bi-OCD according to preferred embodiments, the anodic half reaction can be confined onto the metallic pattern i.e. limiting the place of deposition (referred to as “selective deposition”) inside the holes 33 of the metallic pattern 32 as shown in FIG. 6. The metallic pattern 32 is then acting as anode instead of the back side of the substrate 1 such that only the front side of the (p-type) substrate 1 needs to be in contact with the electrolyte (only one electrolyte is required) and deposition is taking place inside 32 the pattern onto the front side of the p-type substrate 1.

Alternatively, in case of an n-type substrate, the cathodic half reaction is confined to selectively onto the metallic pattern 32 limiting the place of deposition (referred to as “selective deposition”) onto the metallic pattern 32 as shown in FIG. 5. The openings (holes) 33 in between the metallic pattern are then acting as anode instead of the back side of the substrate 1 such that only the front side of the substrate 1 needs to be in contact with the electrolyte (only one electrolyte is required) and deposition of the metallic compound 35 is taking place onto the metallic pattern 32 onto the front side of the substrate and the openings 34 are acting as anode.

After covering the front side of the substrate with a metallic pattern such that the deposition of the metallic compound takes place selectively into the openings (pores) of the pattern or onto the pattern, higher illumination 9 of the front side of the substrate is performed to provide a driving force to separate the cathodic and anodic partial reactions. More specifically light is used to create a potential difference.

In case a p-type semiconducting substrate is used, the front side of the substrate is more illuminated 9 than the back side of the substrate and the deposition is taking place inside the metallic pattern onto the front side of the p-type substrate as shown in FIG. 6. In case an n-type semiconducting substrate is used, the front side of the substrate is more illuminated 9 than the back side of the substrate and deposition of the metallic compound 35 is taking place onto the metallic pattern as shown in FIG. 5.

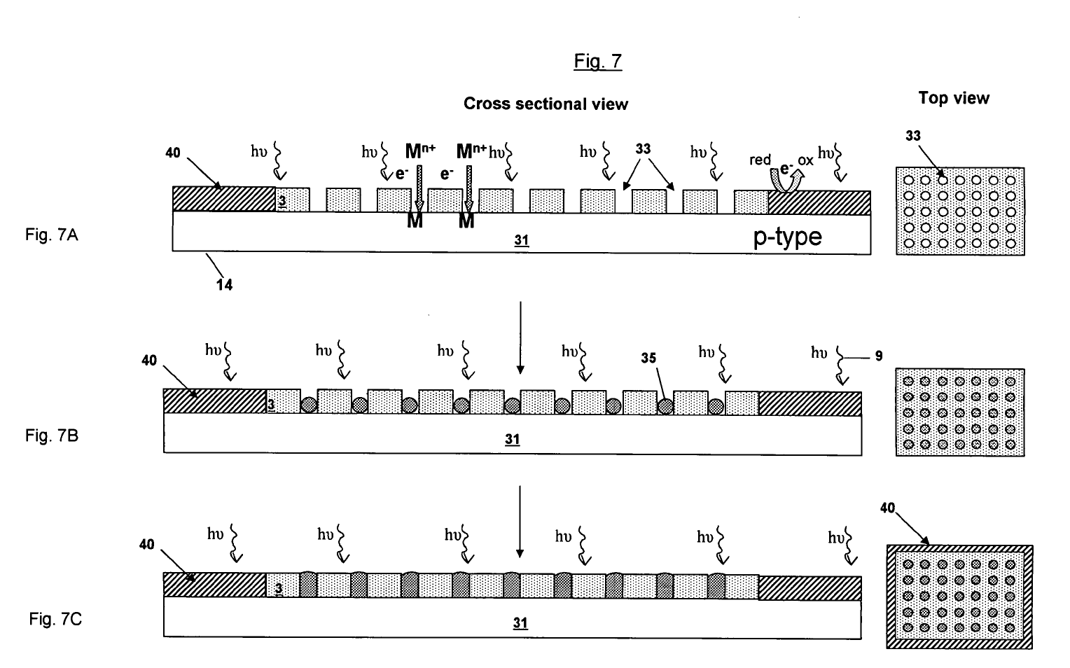

In a fourth and also preferred alternative of the above described embodiments and as shown in FIG. 7 an extra structure is deposited onto the front side of the substrate, the extra structure is then acting as an anode and both oxidation and deposition reactions take place at the front side of the substrate such that only the front side of the substrate is in contact with the electrolytic solution.

In FIG. 7 an extra metal comprising structure 40 (e.g. comprising Ti (TiN), Ta (TaN), W, and the like) is present on the front side of the substrate 1. The substrate 1 is selected from a p-type semiconducting material as described in the first preferred embodiment. The extra metal comprising structure 40 is then acting as an anode and both oxidation and deposition reactions take place at the front side of the substrate such that only the front side of the substrate is in contact with the electrolytic solution.

To realize a selective deposition onto the substrate 1 of the metallic compound, the front side of the substrate 1 is partly covered with an insulating pattern 32 to achieve a selective photo Bi-OCD process. The pattern is an insulating pattern 32 as described in the second preferred embodiment above such that no deposition of the metallic compound 35 is achieved on the pattern 32 or in other words to avoid deposition onto the surface of the pattern 32.

Most preferred, higher illumination 9 on the front side of the substrate is performed to provide a driving force to separate the cathodic and anodic partial reactions.

Alternatively, higher illumination 9 on the back side of the substrate is performed to separate the cathodic and anodic partial reactions.

The illuminance of the higher illuminated side of the substrate is higher than 105 lux (lumen per square meter) and preferably ranges between 10⁵ to 10⁹ lux.

The illuminance of the lower illuminated side of the substrate is lower than 0.5 lux (lumen per square meter) and preferably ranges between 10⁻⁵ to 0.1 lux.

More specifically light is used to create a potential difference.

### EXAMPLE 1

### Selective Photo-Electroless Bi-ECP of Gold in Patterned Silicon via Holes

FIG. 7 illustrates the selective photo-electroless Bi-ECP for gold deposition in patterned silicon via holes. Gold (Au) was deposited on SiO₂ in patterned contact holes on a p-type Si (100) substrate. The electrolyte used was 10 mM Au(I) S₂O₃/SO₃ solution at room temperature (e.g. T=21° C.) and pH=7.

All references cited herein are incorporated herein by reference in their entirety. To the extent publications and patents or patent applications incorporated by reference contradict the disclosure contained in the specification, the specification is intended to supersede and/or take precedence over any such contradictory material.

The term “comprising” as used herein is synonymous with “including,” “containing,” or “characterized by,” and is inclusive or open-ended and does not exclude additional, unrecited elements or method steps.

All numbers expressing quantities of ingredients, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should be construed in light of the number of significant digits and ordinary rounding approaches.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention as embodied in the attached claims.

What is claimed is:

1. A method for electroless deposition of a metallic compound onto a top surface of a semiconducting substrate, comprising the steps of:
contacting a first side of a semiconducting substrate with a first electrically conductive electrolyte comprising dissolved metal ions of a metallic compound;
contacting a second side of the semiconducting substrate opposite the first side with a second electrically conductive electrolyte; and
providing an electrical conductive path between the first electrically conductive electrolyte and second electrically conductive electrolyte;
wherein the first side of the semiconducting substrate is illuminated differently than the second side of the semiconducting substrate.

2. The method of claim 1, wherein the semiconducting substrate is an n-type semiconducting substrate, and wherein the second side of the semiconducting substrate is more illuminated than the first side of the semiconducting substrate.

3. The method of claim 1, wherein the semiconducting substrate is a p-type semiconducting substrate, and wherein the first side of the substrate is more illuminated than the second side of the substrate.

4. The method of claim 1, wherein an intensity of illumination on a higher illuminated side of the semiconducting substrate is at least 50% higher than an intensity of illumination on a lower illuminated side of the semiconducting substrate.

5. The method of claim 1, wherein an intensity of illumination on a higher illuminated side of the semiconducting substrate is at least 100% higher than an intensity of illumination on a lower illuminated side of the semiconducting substrate

6. The method of claim 1, further comprising, prior to the steps of contacting, a step of providing on the semiconducting substrate a layer into which openings are created to form a pattern.

7. The method of claim 1, wherein the first side of the semiconducting substrate is at least partly covered with an insulating pattern such that deposition of the metallic compound takes place selectively into the openings of the pattern.

8. The method of claim 7, wherein the insulating pattern comprises at least one material selected from the group consisting of oxides, alumina, organic polymeric materials, low-k dielectric materials, zeolites, porous oxides, and combinations thereof.

9. The method of claim 7, wherein the semiconducting substrate is an n-type semiconducting substrate, and wherein the first side of the substrate is at least partly covered with a metal comprising pattern such that the deposition of the metallic compound takes place selectively onto a surface of the pattern.

10. The method of claim 9, wherein the metal comprising pattern comprises a metal selected from the group consisting of TiN, TaN, W, and combinations thereof.

11. The method of claim 7, wherein the semiconducting substrate is a p-type semiconducting substrate, and wherein the first side of the substrate is at least partly covered with a metal comprising pattern such that the deposition of the metallic compound takes place selectively in the openings of the pattern.

12. The method of claim 11, wherein the metal comprising pattern comprises a metal selected from the group consisting of TiN, TaN, W, and combinations thereof.

13. The method of claim 1, wherein the semiconducting substrate is an n-type semiconducting substrate comprising at least one material selected from the group consisting of Si, Ge, doped GaAs, and combinations thereof, wherein the doped GaAs is doped with a group III element selected from the group consisting of B, Al, Ga, In, Tl, and combinations thereof.

14. The method of claim 1, wherein the semiconducting substrate is a p-type semiconducting substrate comprising at least one material selected from the group consisting of Si, Ge, doped GaAs, and combinations thereof, wherein the doped GaAs is doped with a group V element selected from the group consisting of N, P, As, Sb, Bi, and combinations thereof.

15. The method of claim 1, wherein the substrate is a light sensitive metal oxide selected from the group consisting of In₂O₃, TiO₂, SnO₂, and combinations thereof.

16. The method of claim 1, wherein the first electrically conductive electrolyte comprises at least one dissolved metal ion selected from the group consisting of Ni²⁺, Co²⁺, Cu²⁺, In³⁺, Au⁺, Au³⁺, Fe²⁺, Fe³⁺, Pt²⁺, Pd²⁺, Pb²⁺, Sb³⁺, Bi³⁺, Zn²⁺, Ga³⁺, Ge⁴⁺, R³⁺, R²⁺, inorganic complexes thereof, organic complexes thereof, alloys thereof, and combinations thereof, wherein the alloy thereof comprise least one material selected from the group consisting of W. Mo, V, Cr, and Mn.

17. The method of claim 16, wherein a total concentration of metal ions in the first electrically conductive electrolyte is from 1 mM to 1M.

18. The method of claim 1, wherein the second electrically conductive electrolyte comprises at least one anion selected from the group consisting of OH⁻, Cl⁻, NO³⁻, SO₄²⁻, PO₄³⁻, S₂O₃²⁻, SO₃²⁻, I⁻, I₃⁻, IO₃⁻, Br⁻, BrO₃⁻, sulfamate, fluoborate, borate, fluoride based solutions, and mixtures thereof, and at least one counter cation selected from the group consisting of Na⁺, K⁺, Ca²⁺, Al³⁺, Li⁺, NH₄⁺, H⁺, and combinations thereof.

19. The method of claim 18, wherein a total concentration of anions in the second electrically conductive electrolyte is from 1 mM to 6M.

20. The method of claim 1, wherein the electrical conductive path between the first conductive electrolyte and the second conductive electrolyte comprises a salt bridge.

21. The method of claim 6, wherein the first side of the semiconducting substrate is more illuminated than the second side of the semiconducting substrate, wherein the first side of the semiconducting substrate further comprises an extra metallic comprising structure configured to act as anode in a bipolar open-circuit deposition such that only the first side of the semiconducting substrate is contacted to the first electrically conductive electrolyte, wherein the second side of the semiconducting substrate is dry, such that deposition of the metallic compound takes place selectively in the openings of the insulating pattern.

22. The method of claim 21, wherein the semiconducting substrate is a p-type semiconducting substrate.

23. A device obtained by the method of claim 6, wherein a filling yield of metal ions in the openings in the pattern is higher than 90%.

24. A device obtained by the method of claim 6, wherein a filling yield of metal ions in the openings in the pattern is higher than 95%.

25. A device obtained by the method of claim 6, wherein a filling yield of metal ions in the openings in the pattern is higher than 99%.

26. Use of the method of claim 1 in a method for selective deposition of metallic nanoparticles configured for use as catalyst for growth of semiconductor nanowires or carbon nanotubes.
